(19) United States
(12) Patent Application Publication
(10) Pub. No.: US 2025/0341479 A1
(43) Pub. Date: Nov. 6, 2025

(54) METROLOGY SYSTEM USING MULTIPLE RADIATION SPOTS

(71) Applicant: ASML Netherlands B.V., Veldhoven (NL)

(72) Inventors: Simon Reinald Huisman, Eindhoven (NL); Sebastianus Adranus GOORDEN, Eindhoven (NL)

(73) Assignee: ASML Netherlands B.V., Veldhoven (NL)

(21) Appl. No.: 18/870,089

(22) PCT Filed: Jul. 13, 2023
(86) PCT No.: PCT/EP2023/069509

§ 371 Date: Nov. 27, 2024

Related U.S. Application Data
(60) Provisional application No. 63/392,044, filed on Jul. 25, 2022.

(51) Int. Cl. G01N 21/956; G02B 5/02; G03F 7/00

(52) U.S. Cl. CPC G01N 21/956; G02B 5/021; G02B 5/0252; G02B 5/0278; G03F 7/70625; G03F 7/70633; G03F 7/70653; G03F 7/706837; G03F 7/706847; G03F 7/706849; G03F 7/706851; G01N 2021/95676

(57) ABSTRACT

An inspection system includes a radiation source, first and second optical structures, and a detection system. The radiation source generates beams of radiation. An image formed by the beams includes radiation spots corresponding to the beams. Diameters of the radiation spots is less than a dimension of a target and the radiation spots are non-overlapping. The first optical structure routes the beams toward the target so as to project the radiation spots on the target and generate scattered radiation from the target. The second optical structure collects the scattered radiation from the target. The detection system receives the scattered radiation collected by the second optical structure and generates measurement signals. Each of the measurement signals corresponds to each of the radiation spots.

### CROSS-REFERENCE TO RELATED APPLICATIONS

This application claims priority of U.S. application 63/392,044 which was filed on Jul. 25, 2022 and which is incorporated herein in its entirety by reference.

### FIELD

The present disclosure relates to inspection systems, for example, a metrology system for measuring target marks in used in lithographic processes.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

A lithographic system can output only a finite number of fabricated devices in a given timeframe. To reduce fabrication time, lithographic systems can increase measurement speeds, but this strategy tends to reduce measurement accuracy.

### SUMMARY

Accordingly, it is desirable to improve fabrication speed and throughput without sacrificing lithographic accuracy. For example, optical inspection processes can be performed faster based on aspects described herein by increasing the measurement radiation dose in a manner that circumvents certain limitations associated with higher radiation intensities.

In some aspects, an inspection system can comprise a radiation source configured to generate beams of radiation. An image formed by the beams can comprise radiation spots corresponding to the beams. Diameters of the radiation spots can each be smaller than a dimension of a target. The radiation spots can be non-overlapping. The inspection system can further comprise a first optical structure configured to route the beams toward the target so as to project the radiation spots on the target and to generate scattered radiation from the target. The inspection system can further comprise a second optical structure configured to collect the scattered radiation from the target. The inspection system can further comprise a detection system configured to receive the scattered radiation collected by the second optical structure and to generate measurement signals. Each of the measurement signals can correspond to each of the radiation spots.

In some aspects, a lithographic apparatus can comprise an illumination system configured to illuminate a pattern of a patterning device. The lithographic apparatus can further comprise a projection system configured to project an image of the pattern onto a substrate. The lithographic apparatus can further comprise an inspection system. The inspection system can comprise a radiation source configured to generate beams of radiation. An image formed by the beams can comprise radiation spots corresponding to the beams. Diameters of the radiation spots can each be smaller than a dimension of a target. The radiation spots can be non-overlapping. The inspection system can further comprise a first optical structure configured to route the beams toward the target so as to project the radiation spots on the target and to generate scattered radiation from the target. The inspection system can further comprise a second optical structure configured to collect the scattered radiation from the target. The inspection system can further comprise a detection system configured to receive the scattered radiation collected by the second optical structure and to generate measurement signals. Each of the measurement signals can correspond to each of the radiation spots.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A, 4B, 5, and 6 show inspection systems, according to some aspects.

FIGS. 7 and 8 show scanning processes using multiple radiation spots, according to some aspects.

FIGS. 9-12 show inspection systems, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

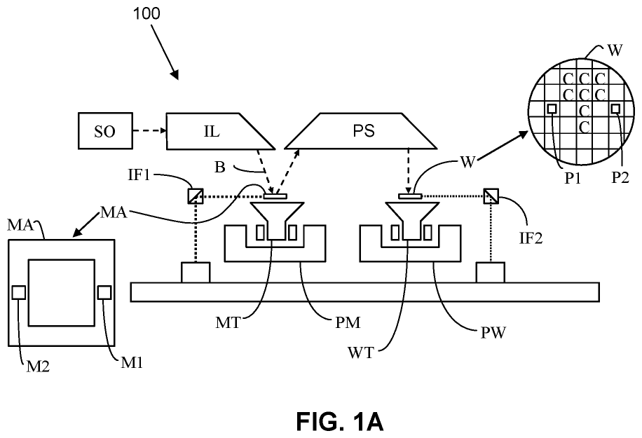

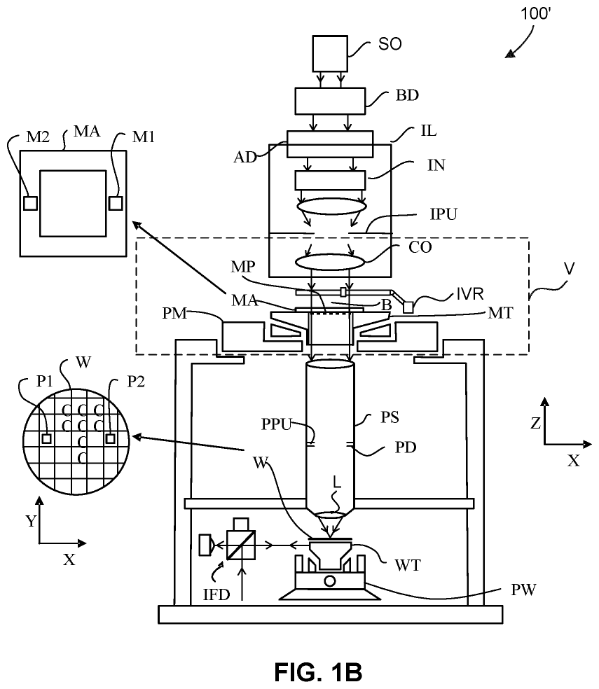

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further aspect, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

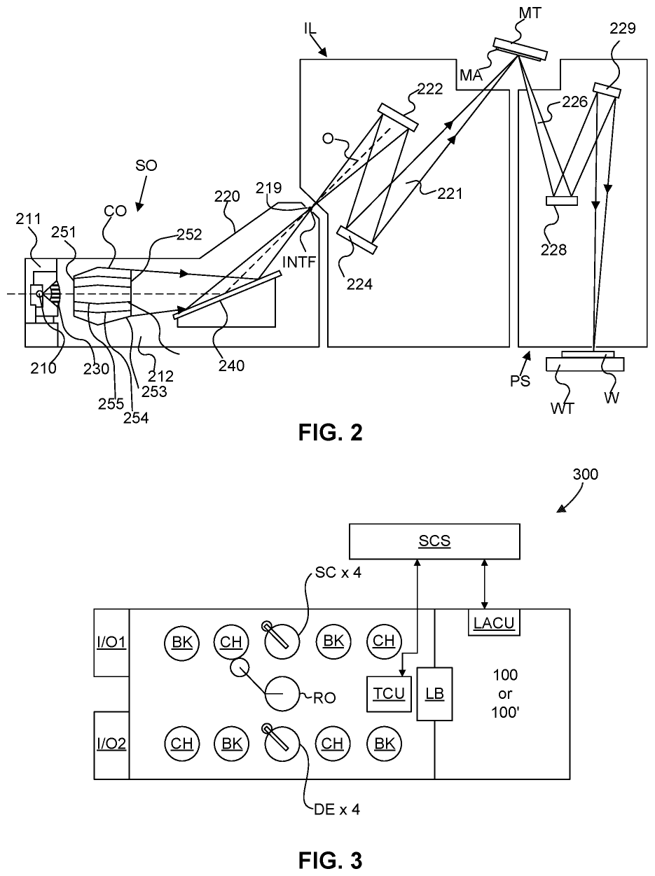

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre-and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

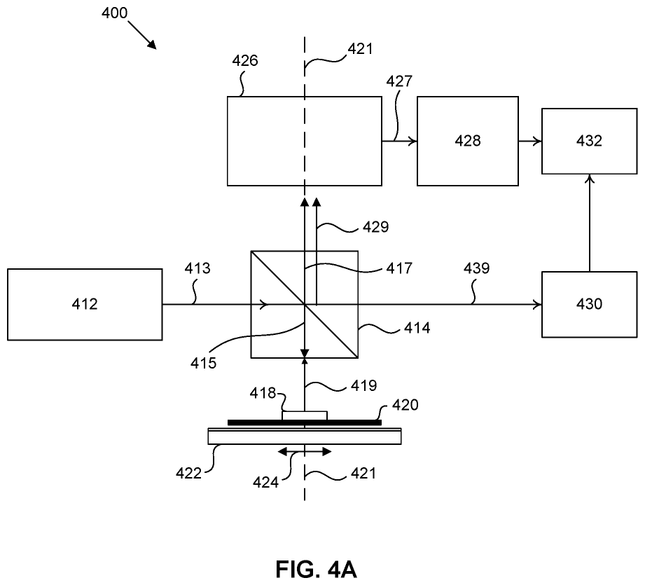

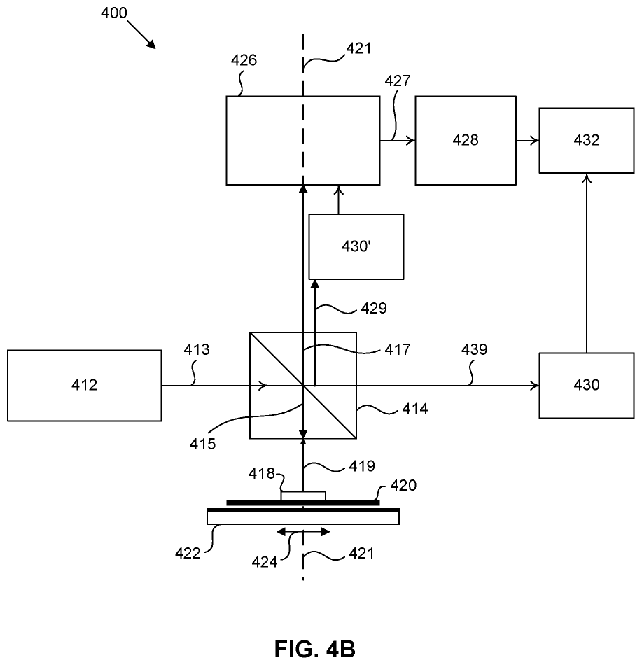

FIG. 4A shows a cross-sectional view of an inspection system 400 (or metrology system) that can be implemented as a part of lithographic apparatus 100 or 100′, according to some aspects. In some aspects, inspection system 400 can be configured to align a substrate (e.g., substrate W) with respect to a patterning device (e.g., patterning device MA). Inspection system 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like, can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection system 400 can include an illumination system 412, a beam splitter 414, an interferometer 426, a detector 428, a beam analyzer 430, and a processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection system 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection system 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection system 400 or any other reference element such that the center of symmetry of alignment mark or target 418 can be known with reference to inspection system 400 or any other reference element. Beam analyzer 430 can be a point or an imaging polarimeter with some form of wavelength-band selectivity. In some aspects, beam analyzer 430 can be directly integrated into inspection system 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection system 400, or any other reference element, such that the center of symmetry of alignment mark or target 418 can be known with reference to inspection system 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection system 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection system 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some aspects, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection system 400.

### Example High-Dose Inspection System

In some aspects, the term “throughput” can be used to characterize a rate of lithographic fabrication. For example, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each part of the process can involve technical choices that balance quality and drawbacks (e.g., sub-nanometer accuracy, high yield vs. slower fabrication, cost, or the like). For example, to improve pattern-transfer accuracy, lithography can include inspection of printed marks on a substrate. The inspection can be used to ascertain a conformity of a printed pattern on a substrate or to align a substrate in order to properly receive a new pattern. However, the added time of the inspection process can greatly affect throughput.

In some aspects, sub-nanometer fabrication accuracy can be achieved by leveraging inspection system 400 to perform alignments of substrates or to check critical dimensions and overlay. The accuracy of such inspection tools can be inherently limited (e.g., apparatus noise, shot noise, Rayleigh criterion, or the like). In particular, it is of great value to increase signal-to-noise (SNR) ratio of any given measurement. SNR can be increased by increasing an exposure dose on a target. In one example, dose can be increased by allowing a target to be irradiated for a longer period of time. However, the additional time can reduce throughput. In another example, dose can be increased by increasing radiation intensity (e.g., more photons per unit time, higher fluence, higher irradiance, or the like). However, a constraint is that merely increasing the intensity at a location of a target can damage or ablate the target. A target can be considered damaged by the high-intensity radiation if the intensity is high enough to deform the target such that inspection accuracy is appreciably impacted (e.g., resulting in higher rates of pattern-transfer non-conformity).

In some aspects, a small spot of high-intensity radiation can be spread across a target surface. Particularly, a power of the radiation per unit surface area can be reduced by spreading the radiation in order to compensate for the overall higher radiation dose. However, the optical operating principle for the small spot can rendered inadequate for performing inspection using the spread radiation. Aspects of inspection apparatuses described herein can implement high-power radiation to increase inspection accuracy and speed while mitigating drawbacks associated with the high-power radiation.

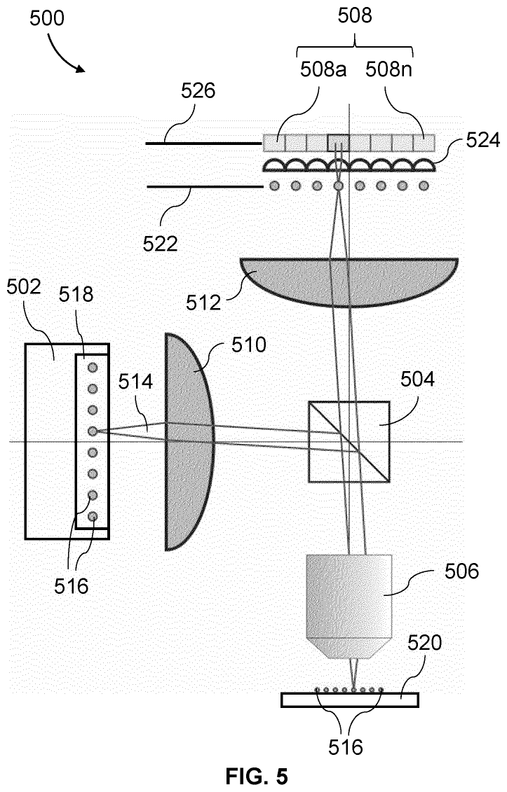

FIG. 5 shows an inspection system 500, according to some aspects. In some aspects, inspection system 500 can comprise a radiation source 502, optical structures 504 and 506, and a detection system 508. Inspection system 500 can also comprise lens systems 510 and 512. Though lens systems 510 and 512 are illustrated as single lenses, lens systems 510 and/or 512 can each comprise a system of lenses.

In some aspects, inspection system 500 can be used to perform the various inspection operations described for inspection system 400 (FIG. 4) (e.g., wafer alignment, critical dimension inspection, overlay inspection, or the like). However, a difference is that inspection system 500 implements structures for sourcing and detection of multiple beams of radiation in a single inspection system. The arrangement of inspection system 500 can occupy less space and can be more cost-efficient than scaling multiple inspection systems 400 side by side to achieve the multiple beams function.

In some aspects, radiation source 502 can generate a plurality of beams of radiation 514 that correspond to an image of radiation spots 516, as opposed to a single spot. Beams of radiation 514 can comprise coherent or incoherent radiation. Radiation source 502 can comprise an optical device 518 for generating radiation spots 516. To list a few non-limiting examples, optical device 518 can comprise a diffraction structure, a multi-aperture structure, a spatial light modulator (SLM) (e.g., digital micromirror device, liquid crystal device, or the like), a holographic structure, an array of optical fibers, or the like. In some aspects a diameter of each of radiation spots 516 can be smaller than a dimension of a target 520. The smaller spot allows for resolving smaller features of the target. A dimension of target 520 can be defined as a width or length of the overall structure. For example, if target 520 has a grating structure, then the dimension can be the width along the pitch of the gratings, beginning at a grating line on one end and ending at the grating line at the opposite end. In some aspects, radiation spots 516 can be non-overlapping so as to prevent cross talk between signals corresponding to each of radiation spots 516.

In some aspects, optical structure 504 (e.g., a “first optical structure”) can comprise a beam splitter, a reflective structure, a refractive structure, a waveguide, or the like, or a combination thereof. Optical structure 504 can route beams of radiation 514 toward a surface of a target 520 so as to project radiation spots 516 on target 520 and to generate scattered radiation from target 520. Optical structure 506 (e.g., a “second optical structure”) can comprise a lens objective, a reflective structure, a refractive structure, or the like, or a combination thereof. Optical structure 506 can focus an image of radiation spots 516 and/or collect the scattered radiation from target 520.

In some aspects, enumerative adjectives (e.g., “first,” “second,” “third,” or the like) can be used to distinguishing like elements without establishing an order, hierarchy, or numeric correspondence (unless otherwise noted). For example, the terms “first optical structure” and “second optical structure” can distinguish two optical structures without specifying a particular order or hierarchy. Furthermore, an element in a drawing is not limited to any particular enumerative adjective. For example, optical structure 504 can be referred to as a first optical structure or a second optical structure, in which case other optical structures can be ascribed different enumerative adjectives.

In some aspects, radiation source 502 can output beams of radiation 514 with an aggregate power density sufficient to damage target 520. However, radiation source 502 can spread the aggregate power density among the beams such that an average power density of each of the beams is insufficient to damage target 520. With multiple radiation spots 516 generating scattered radiation from target 520, the analysis of the scattered radiation can encompass additional considerations compared to a simpler analysis in single-spot metrology.

In some aspects, detection system 508 can receive the scattered radiation collected by optical structure 506. Detection system 508 can generate measurement signals that correspond to each of radiation spots 516. Inspection system 500 can comprise an analyzer to analyze each of the measurement signals corresponding to each of radiation spots 516 to determine a value of a property of target 520. Some non-limiting examples of a property of target 520 can include alignment position, critical dimensions, overlay offset, or the like. The analyzer can be, for example, processor 432 (FIG. 4). In the context of a diffraction target 520 (e.g., a grating), when analyzing specular reflection scattering, each of radiation spots 516 can correspond to a zeroth order. Each of the zeroth orders can be received at corresponding ones of detection elements 508a-508n (n is arbitrary) of detection system 508. Detection elements 508a-508n can be an array of detectors (e.g., 1D or 2D array), pixels of an image capture device (e.g., a camera), or the like. If a camera is used, then analyzer 432 (FIG. 4) can be programmed to apportion corresponding pixels to each of the zeroth orders. The functions can be scaled up for higher diffraction orders, for example, + and − orders used in darkfield metrology. Two or more detector elements can correspond to one of radiation spots 516. Radiation spots 516 can be non-overlapping so as to avoid cross-talk between measurement signals.

In some aspects, images of spots corresponding to the diffraction orders can form at an image plane 522 (or field plane). While FIG. 5 illustrates a non-limiting example of zeroth diffraction order ray traces, it should be understood that higher diffraction orders can propagate according to their respective diffractive interaction with target 520. Inspection system 500 can comprise a lens array 524. Due to collimation by lens array 524, a pupil plane 526 can be disposed downstream of lens array 524. Pupil plane 526 can be a Fourier conjugate of image plane 522. Detection system 508 can be disposed at pupil plane 526. That is, lens array 524 can be disposed between image plane 522 and detection system 508. Each lens element of lens array 524 can correspond to each of detection elements 508a-508n. The arrangement of lens array 524 and detection system 508 can allow analysis of a pupil contribution of each of radiation spots 516.

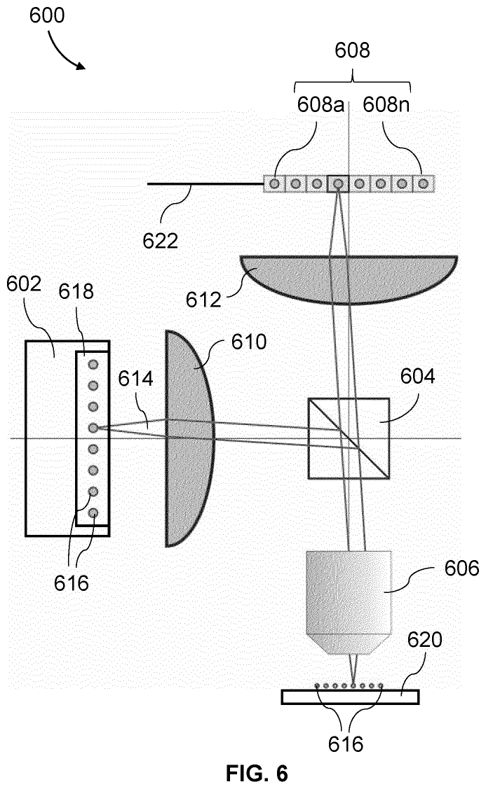

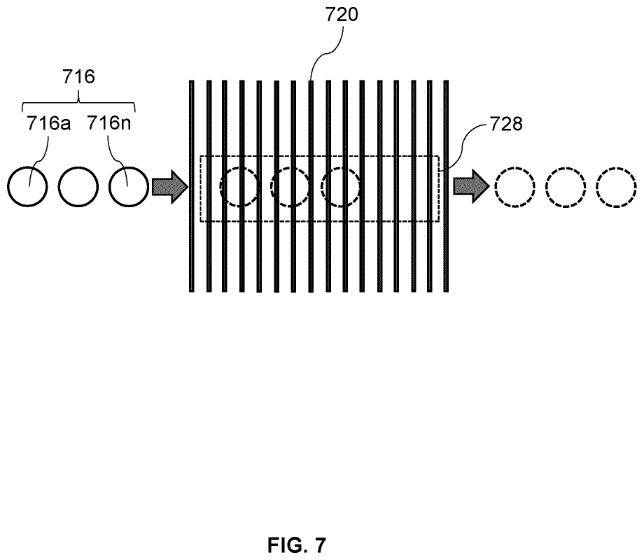

FIG. 6 shows an inspection system 600, according to some aspects. In some aspects, inspection system 600 can comprise structures and functions similar to inspection system 500 that were described in reference to FIG. 5. Therefore, unless otherwise noted, descriptions of elements of FIG. 5 can also apply to corresponding elements of FIG. 6 (e.g., reference numbers sharing the two right-most numeric digits) and will not be rigorously reintroduced. Elements in FIG. 6 can include a radiation source 606, optical structures 604 and 606, a detection system 608 with detection elements 608a-608n, lens systems 610 and 612, beams of radiation 614, radiation spots 616, optical device 618, target 620, and image plane 622—the structures and functions of which can be inferred from descriptions of corresponding elements of FIG. 5.

In some aspects, in contrast to the arrangement in FIG. 5, detection system 608 can be disposed at image plane 622. Images of spots corresponding to the diffraction orders can be focused at detection system 608. The optical arrangement can allow analysis of re-projected scattering of each of radiation spots 616.

In some aspects, radiation spots 516 (FIG. 5) or 616 (FIG. 6) can be moved across target 520 (FIG. 5) or 620 (FIG. 6) to determine how the measurement signals vary as a result of being at various different positions relative to the target.

In some aspects, optical structure 604 can be a polarizing beam splitter. In this scenario, scattered radiation received at detection elements 608a-608n can have a polarization that is orthogonal to a polarization of the incident radiation that irradiates target 620.

FIG. 7 shows a scanning process using radiation spots 716, according to some aspects. In some aspects, radiation spots 716 can comprise radiation spots 716a-n. Here, n can be three, but it should be understood that n can be 2 or more. Radiation spots 716 can be generated by inspection systems 500 or 600 (FIG. 5 or 6). Unless otherwise noted, descriptions of elements of FIGS. 5 and 6 can also apply to corresponding elements of FIG. 7 (e.g., reference numbers sharing the two right-most numeric digits). Though not shown in FIG. 5 or 6, it should be appreciated that inspection systems 500 and/or 600 can comprise an actuator for moving radiation spots 716 relative to target 720. Moving target 720 relative radiation spots 716 can also be considered, from the rest frame of target 720, as moving radiation spots 716 relative to target 720. The scanning can be performed using a continuous motion or discrete steps.

In some aspects, a target 720 can comprise a region 728. Radiation spots 716 can be scanned across region 728 such that each of radiation spots 716a-n can survey region 728. In other words, a same region of target 720 can be scanned three times. Compared to a method that uses only a single radiation spot at a same scanning speed, the method illustrated by FIG. 7 can effectively increase the radiation dose by n times (e.g., 3 times in this non-limiting example). In this manner, the SNR of inspection systems 500 and 600 (FIGS. 5 and 6) can be increased compared to single-spot inspection systems. An analyzer can then analyze each measurement signal corresponding to each of radiation spots 716 to determine a value of a property of target 720. The analyzing can comprise aggregating the measurement signals (e.g., averaging, integrating, or the like). In one non-limiting example, SNR can increase in proportion to a square root of the dose. With higher SNR, the accuracy of determining value of a property of target 720 can be increased (without damaging target 720 as a result of the spreading of the radiation power).

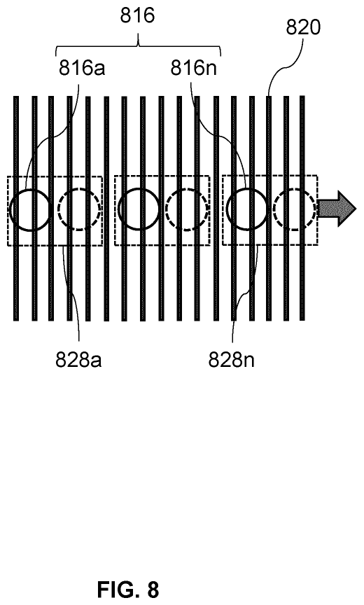

FIG. 8 shows a scanning process using radiation spots 816, according to some aspects. In some aspects, radiation spots 816 can comprise radiation spots 816a-n. Here, n can be three, but it should be understood that n can be 2 or more. Radiation spots 816 can be generated by inspection systems 500 or 600 (FIG. 5 or 6). Unless otherwise noted, descriptions of elements of FIGS. 5 and 6 can also apply to corresponding elements of FIG. 8 (e.g., reference numbers sharing the two right-most numeric digits). Though not shown in FIG. 5 or 6, it should be appreciated that inspection systems 500 and/or 600 can comprise an actuator for moving radiation spots 816 relative to target 820. Moving target 820 relative radiation spots 816 can also be considered, from the rest frame of target 820, as moving radiation spots 816 relative to target 820. The scanning can be performed using a continuous motion or discrete steps.

In some aspects, a target 820 can comprise regions 828a-n. Here, n can be the same as the number of radiation spots used. Radiation spots 816 can be scanned across regions 828a-n such that each of radiation spots 816a-n surveys a corresponding one of regions 828a-n. In other words, different of target 820 can be scanned once (though regions are not the same, there can be partial overlap of regions). The scanning can be performed at a slower speed compared to the method illustrated in FIG.

7. For example, the scanning in FIG. 8 can be performed such that radiation spots 816 are incident on target 820 for an amount of time that it takes for a single radiation spot to scan across all of regions 828a-n. In this manner, the method illustrated by FIG. 8 can effectively increase the radiation dose by n times (e.g., 3 times in this non-limiting example). Correspondingly, the SNR of inspection systems 500 and 600 (FIGS. 5 and 6) can be increased compared to single-spot inspection systems.

As it was with FIG. 7, an analyzer can then analyze each measurement signal corresponding to each of radiation spots 816 to determine a value of a property of target 820. The analyzing can comprise aggregating the measurement signals (e.g., averaging, integrating, or the like). In one non-limiting example, SNR can increase in proportion to a square root of the dose. With higher SNR, the accuracy of determining value of a property of target 820 can be increased (without damaging target 820 as a result of the spreading of the radiation power).

While FIGS. 7 and 8 show example one-dimensional inline arrangements of radiation spots, the present disclosure is not so limited. It is also envisaged to have radiation spot arrangements in two dimensions (e.g., square pattern, honeycomb pattern, or the like).

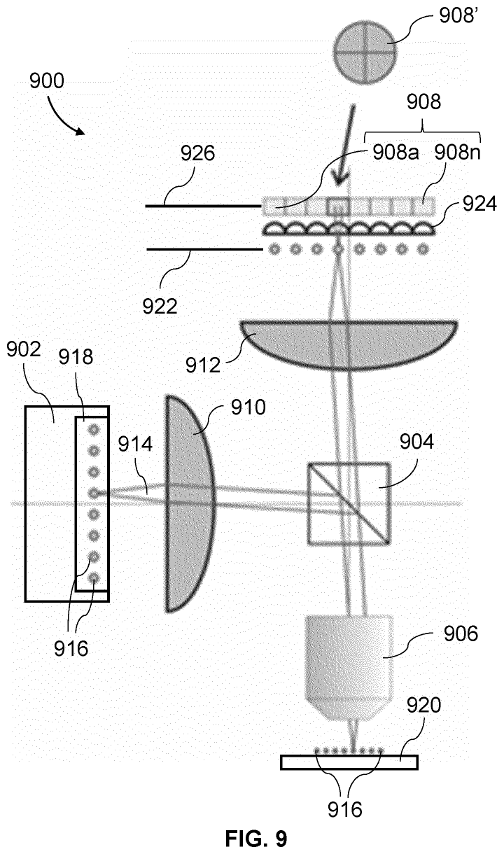

Inspection systems and methods disclosed herein can be enhanced with additional features. FIG. 9 shows an inspection system 900, according to some aspects. In some aspects, inspection system 900 can comprise structures and functions similar to those described in reference to FIGS. 5-8. Therefore, unless otherwise noted, descriptions of elements of FIGS. 5-8 can also apply to corresponding elements of FIG. 9 (e.g., reference numbers sharing the two right-most numeric digits) and will not be rigorously reintroduced. Elements in FIG. 9 can include a radiation source 902, optical structures 904 and 906, a detection system 908 with detection elements 908a-908n, lens systems 910 and 912, beams of radiation 914, radiation spots 916, optical device 918, target 920, image plane 922, lens array 924, and pupil plane 926—the structures and functions of which can be inferred from descriptions of corresponding elements of FIGS. 5-8.

In some aspects, each of detection elements 908a-908n can each comprise a quadrant cell photodetector 908′ (non-limiting example). Other examples can include other types of photodetectors, such balanced photodiodes. Such photodetectors can measure extremely small changes in the position of a light beam and can be used for centering, nulling, detecting and measuring position displacements, or the like.

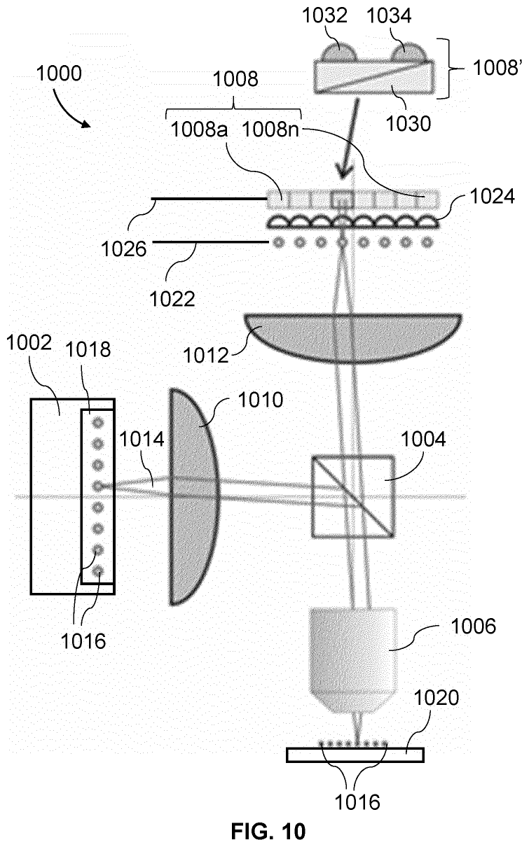

FIG. 10 shows an inspection system 1000, according to some aspects. In some aspects, inspection system 1000 can comprise structures and functions similar to those described in reference to FIGS. 5-9. Therefore, unless otherwise noted, descriptions of elements of FIGS. 5-9 can also apply to corresponding elements of FIG. 10 (e.g., reference numbers sharing the two right-most numeric digits) and will not be rigorously reintroduced. Elements in FIG. 10 can include a radiation source 1002, optical structures 1004 and 1006, a detection system 1008 with detection elements 1008a-1008n, lens systems 1010 and 1012, beams of radiation 1014, radiation spots 1016, optical device 1018, target 1020, image plane 1022, lens array 1024, and pupil plane 1026—the structures and functions of which can be inferred from descriptions of corresponding elements of FIGS. 5-9.

In some aspects, each of detection elements 1008a-1008n can each comprise a birefringence-based detector 1008′ (non-limiting example). Birefringence-based detector 1008′ can comprise a Wollaston prism 1030, and detection elements 1032 and 1034 (e.g., one element for each of polarizations H and V).

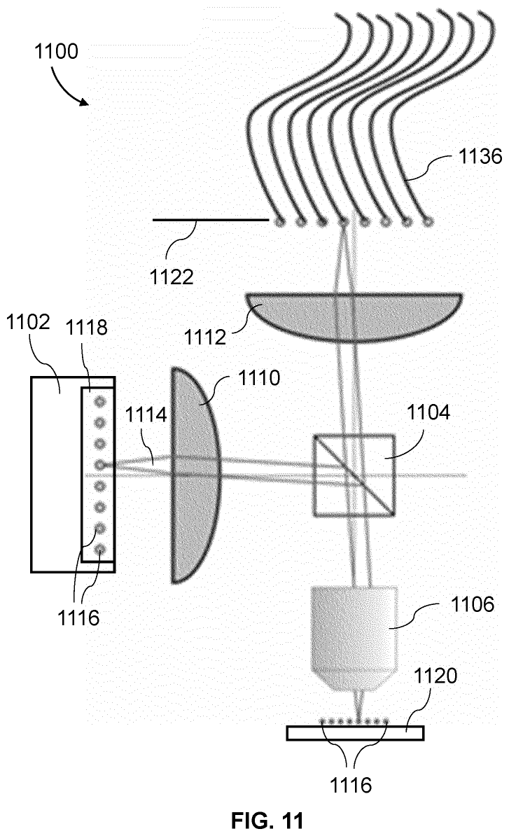

FIG. 11 shows an inspection system 1100, according to some aspects. In some aspects, inspection system 1100 can comprise structures and functions similar to those described in reference to FIGS. 5-10. Therefore, unless otherwise noted, descriptions of elements of FIGS. 5-10 can also apply to corresponding elements of FIG. 11 (e.g., reference numbers sharing the two right-most numeric digits) and will not be rigorously reintroduced. Elements in FIG. 11 can include a radiation source 1102, optical structures 1104 and 1106, lens systems 1110 and 1112, beams of radiation 1114, radiation spots 1116, optical device 1118, target 1120, image plane 1122—the structures and functions of which can be inferred from descriptions of corresponding elements of FIGS. 5-10.

In some aspects, a detection system of inspection system 1100 is not shown (e.g., off the page). Inspection system 1100 can comprise an optical fiber array 1136 to guide scattered radiation from target 1120 to the detection system. The input end of optical fiber array 1136 can be disposed at image plane 1122 (or at a pupil plane; not shown).

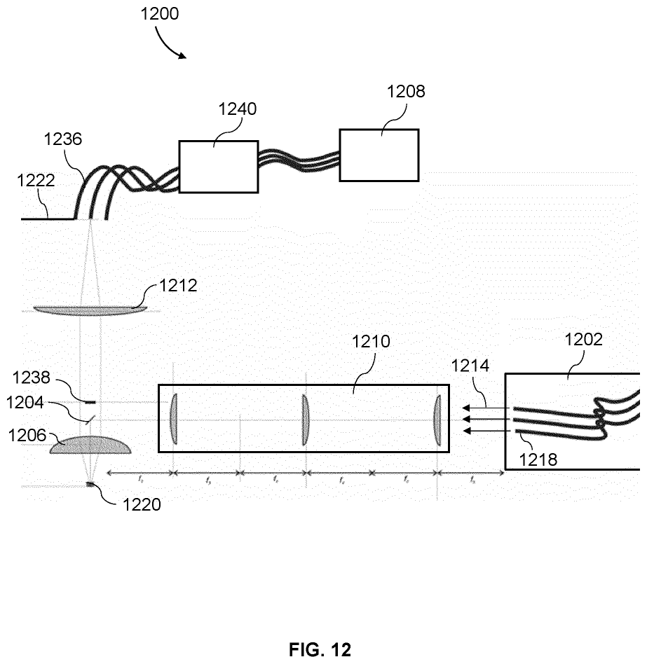

Other fiber-based concepts are envisaged, for example, FIG. 12 shows an inspection system 1200, according to some aspects. In some aspects, inspection system 1200 can comprise structures and functions similar to those described in reference to FIGS. 5-11. Therefore, unless otherwise noted, descriptions of elements of FIGS. 5-11 can also apply to corresponding elements of FIG. 12 (e.g., reference numbers sharing the two right-most numeric digits) and will not be rigorously reintroduced. Elements in FIG. 12 can include a radiation source 1202, optical structures 1204 and 1206, detection system 1208 lens systems 1210 and 1212, beams of radiation 1214, optical device 1218 (e.g., optical fiber array), target 1220, image plane 1222, and optical fiber array 1236-the structures and functions of which can be inferred from descriptions of corresponding elements of FIGS. 5-10. Optical fibers in optical fiber arrays can comprise multimode fibers. The input end of optical fiber array 1236 can be disposed at image plane 1222 (or at a pupil plane; not shown).

In some aspects, inspection system 1200 can also include a blocking device 1238 and a demultiplexer 1240. Blocking device 1238 can be a 0^{th} order stop for darkfield measurements. Demultiplexer 1240 can be used for using multiple wavelength bands in a measurement (e.g., radiation spots having different wavelengths). At least one of the radiation spots produced by optical device 1218 can have multiple wavelength bands. Consequently, the scattered radiation from target 1220 can also have the multiple wavelength bands. Demultiplexer 1240 can be used to separate the wavelength bands of the scattered radiation.

In some aspects, each optical fiber in optical device 1218 can be actuated using actuators. The actuation can allow for each of the radiation spots to be placed at desired depths of focus as well as different arrangements (e.g., inline or two-dimensional array). To account for the movement, each optical fiber in optical device 1236 can also be actuated in a similar manner to accommodate shifts in focus.

In some aspects, radiation spots described in reference to FIGS. 5-12 can be analyzed in a different manner. The following are some examples.

In some aspects, radiation spots described in reference to FIGS. 5-12 can be made “incoherent” with other radiation spots. For example, using different wavelengths for each of the radiation spots. This is useful for mitigating cross talk interference between signals corresponding to different radiation spots.

In some aspects, inspection systems described in reference to FIGS. 5-12 can be used as a hyperspectral sensors by assigning different wavelengths to radiation spots. Demultiplexer 1240 was described in reference to FIG. 12, but it should be understood that the features can also be implemented in systems and methods described in reference to FIGS. 5-11.

In some aspects, inspection systems described in reference to FIGS. 5-12 can be used as 3D confocal miscroscopes capable of acquiring a 3D image data in a single scan. For example, the radiation source can comprise an optical device configured to split source radiation to form the beams of radiation such that the radiation spots have different focal planes and the detection system can comprise detection elements arranged to correspond to the different focal planes.

In some aspects, inspection systems described in reference to FIGS. 5-12 can be used for tomographic reconstruction of the target. For example, each radiation spot can have a different diameter.

In some aspects, inspection system described in reference to FIGS. 5-12 can be implemented with spots having different polarization states. The polarization states can be tailored to the expected response from a given design of a grating target.

The embodiments may further be described using the following clauses:
1. An inspection system comprising:
   a radiation source configured to generate beams of radiation, wherein an image formed by the beams comprises radiation spots corresponding to the beams, wherein a diameter of the radiation spots is less than a dimension of a target and the radiation spots are non-overlapping;
   a first optical structure configured to route the beams toward the target so as to project the radiation spots on the target and to generate scattered radiation from the target;
   a second optical structure configured to collect the scattered radiation from the target; and
   a detection system configured to receive the scattered radiation collected by the second optical structure and to generate measurement signals, wherein each of the measurement signals corresponds to each of the radiation spots.
2. The inspection system of clause 1, wherein the radiation source outputs the beams with an aggregate power density sufficient to damage the target and spreads the aggregate power density among the beams such that an average power density of each of the beams is insufficient to damage the target.
3. The inspection system of clause 1, further comprising an analyzer configured to analyze each of the measurement signals corresponding to each of the radiation spots to determine a value of a property of the target.
4. The inspection system of clause 3, wherein:
   the scattered radiation comprises diffraction orders; and
   the analyzer is configured to determine the value of the property based on analyzing an interference of the diffraction orders.
5. The inspection system of clause 1, wherein:
   the scattered radiation comprises diffraction orders;
   the inspection system further comprises a blocking element configured to block a 0^{th} diffraction order of the scattered radiation.
6. The inspection system of clause 1, further comprising an actuator to move the radiation spots relative to the target.
7. The inspection system of clause 6, wherein:
   the target comprises a region; and
   the actuator is further configured to move the radiation spots such that each of the radiation spots irradiates the region.
8. The inspection system of clause 6, wherein:
   the target comprises regions; and
   the actuator is further configured to move the radiation spots such that each of the radiation spots irradiates a corresponding one of the regions.
9. The inspection system of clause 1, wherein the detection system is disposed at an image plane such that images of the radiation spots are focused at the detection system.
10. The inspection system of clause 1, wherein the detection system is disposed at a pupil plane, wherein the pupil plane is a conjugate of an image plane at which images of the radiation spots are at focus.
11. The inspection system of clause 1, wherein:
   the detection system comprises detection elements, and
   each of the detection elements correspond to each of the radiation spots.
12. The inspection system of clause 1, wherein:
   the detection system comprises a camera;
   the inspection system further comprises an analyzer configured to analyze each of the measurement signals corresponding to each of the radiation spots to determine a value of a property of the target; and
different regions of pixels of the camera correspond to different ones of the radiation spots.
13. The inspection system of clause 1, wherein the radiation source comprises an optical device configured to split source radiation to form the beams.
14. The inspection system of clause 13, wherein the optical device comprises at least one of:
   a diffraction structure;
   a multi-aperture structure;
   a spatial light modulator;
   a holographic structure; or
   an optical fiber array.
15. The inspection system of clause 1, wherein:
   the radiation source comprises an optical device configured to split source radiation to form the beams such that the radiation spots have different focal planes; and
   the detection system comprises detection elements corresponding to the different focal planes.
16. The inspection system of clause 1, wherein:
   at least one of the radiation spots has a wavelength that is different from a wavelength of another one of the radiation spots; and
   the inspection system further comprises a demultiplexer configured to separate wavelengths of the scattered radiation.
17. The inspection system of clause 1, wherein:
   at least one of the radiation spots has multiple wavelength bands; and
   the inspection system further comprises a demultiplexer configured to separate the wavelength bands of the scattered radiation.
18. The inspection system of clause 1, wherein at least a portion of the radiation spots have different diameters.
19. The inspection system of clause 1, wherein at least a portion of the radiation spots have a different polarization states.
20. The inspection system of clause 1, wherein at least a portion of the radiation spots are distributed on the target in an inline arrangement or a two dimensional arrangement.
21. The inspection system of clause 1, at least one of the radiation spots has a beam profile that is different from a beam profile of another one of the radiation spots.
22. The inspection system of clause 1, wherein the first optical structure is a polarizing beam splitter.
23. A lithographic apparatus comprising:
   an illumination system configured to illuminate a pattern of a patterning device;
   a projection system configured to project an image of the pattern onto a substrate; and
   an inspection system comprising:
   a radiation source configured to generate beams of radiation, wherein an image formed by the beams comprises radiation spots corresponding to the beams, wherein a diameter of the radiation spots is less than a dimension of a target and the radiation spots are non-overlapping;
   a first optical structure configured to route the beams toward the target so as to project the radiation spots on the target and to generate scattered radiation from the target;
   a second optical structure configured to collect the scattered radiation from the target; and
   a detection system configured to receive the scattered radiation collected by the second optical structure and to generate measurement signals, wherein each of the measurement signals corresponds to each of the radiation spots.
24. The lithographic apparatus of clause 23, wherein the radiation source outputs the beams with an aggregate power density sufficient to damage the target and spreads the aggregate power density among the beams such that an average power density of each of the beams is insufficient to damage the target.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. An inspection system comprising:
a radiation source configured to generate beams of radiation, wherein an image formed by the beams comprises radiation spots corresponding to the beams, wherein a diameter of the radiation spots is less than a dimension of a target and the radiation spots are non-overlapping;
a first optical structure configured to route the beams toward the target so as to project the radiation spots on the target and to generate scattered radiation from the target;
a second optical structure configured to collect the scattered radiation from the target; and
a detection system configured to receive the scattered radiation collected by the second optical structure and to generate measurement signals, wherein each of the measurement signals corresponds to each of the radiation spots.

2. The inspection system of claim 1, wherein the radiation source outputs the beams with an aggregate power density sufficient to damage the target and spreads the aggregate power density among the beams such that an average power density of each of the beams is insufficient to damage the target.

3. The inspection system of claim 1, further comprising an analyzer configured to analyze each of the measurement signals corresponding to each of the radiation spots to determine a value of a property of the target.

4. The inspection system of claim 3, wherein:
the scattered radiation comprises diffraction orders; and
the analyzer is configured to determine the value of the property based on analyzing an interference of the diffraction orders.

5. The inspection system of claim 1, wherein:
the scattered radiation comprises diffraction orders;
the inspection system further comprises a blocking element configured to block a 0th diffraction order of the scattered radiation.

6. The inspection system of claim 1, further comprising an actuator to move the radiation spots relative to the target.

7. The inspection system of claim 6, wherein:
the target comprises a region; and
the actuator is further configured to move the radiation spots such that each of the radiation spots irradiates the region.

8. The inspection system of claim 6, wherein:
the target comprises regions; and
the actuator is further configured to move the radiation spots such that each of the radiation spots irradiates a corresponding one of the regions.

9. The inspection system of claim 1, wherein the detection system is disposed at an image plane such that images of the radiation spots are focused at the detection system.

10. The inspection system of claim 1, wherein the detection system is disposed at a pupil plane, wherein the pupil plane is a conjugate of an image plane at which images of the radiation spots are at focus.

11. The inspection system of claim 1, wherein:
the detection system comprises detection elements, and
each of the detection elements correspond to each of the radiation spots.

12. The inspection system of claim 1, wherein:
the detection system comprises a camera;
the inspection system further comprises an analyzer configured to analyze each of the measurement signals corresponding to each of the radiation spots to determine a value of a property of the target; and
different regions of pixels of the camera correspond to different ones of the radiation spots.

13. The inspection system of claim 1, wherein the radiation source comprises an optical device configured to split source radiation to form the beams.

14. The inspection system of claim 13, wherein the optical device comprises at least one of:
a diffraction structure;
a multi-aperture structure;
a spatial light modulator;
a holographic structure; or
an optical fiber array.

15. The inspection system of claim 1, wherein:
the radiation source comprises an optical device configured to split source radiation to form the beams such that the radiation spots have different focal planes; and
the detection system comprises detection elements corresponding to the different focal planes.
